(19) United States
(12) Patent Application Publication
(10) Pub. No.: US 2003/0053361 A1
(43) Pub. Date: Mar. 20, 2003

(54) EDRAM based architecture

(76) Inventors: Haitao Zhang, San Diego, CA (US); Stephen Simmonds, San Diego, CA (US); Hanfang Pan, San Diego, CA (US)

Correspondence Address: QUALCOMM Incorporated, Attn: Patent Department, 5775 Morehouse Drive, San Diego, CA, 92121-1714, US

(21) Appl. No.: 10/242,878

(22) Filed: Sep. 11, 2002

Related U.S. Application Data
(60) Provisional application No. 60/324,013, filed on Sep. 20, 2001.

(51) Int. Cl. G11C 7/00

(52) U.S. Cl. 365/222

(57) ABSTRACT

A memory refresh system and method. The inventive system includes a mechanism for selectively refreshing elements of a memory array in response to signals from a conventional memory management system. In the illustrative application, the memory is dynamic random access memory and the inventive system is adapted to provide for selective refresh of those DRAM memory elements to which data has been or will be stored. This allows for the use of advantageous DRAM memory elements while minimizing the power consumption thereof. Consequently, the utility of DRAM memory elements is extended to a variety of power sensitive applications including cellular telephony and mobile computing.

This application claims priority to pending Provisional application No. 60/324,013, filed on Sep. 20, 2001, incorporated herein by reference.

### BACKGROUND OF THE INVENTION

1. Field of Invention

This invention relates to memory architectures. Specifically, the present invention relates to memory architectures used in communication systems.

2. Description of the Related Art

Modern cell phones typically use flash RAM (random access memory) for nonvolatile memory applications, such as program storage, and volatile static RAM also known as “SRAM” for nonvolatile data storage. While SRAM has heretofore been adequate for cellular telephony applications, dynamic RAM or “DRAM” has been preferred for numerous other applications, such as personal computing, due to the smaller size thereof. That is, while SRAM typically requires six transistors per cell, DRAM typically requires only a single transistor per cell. The smaller size of DRAM memory cells allows for greater storage capacity per chip or die unit area.

Unfortunately, unlike SRAM, DRAM must be refreshed periodically. Consequently, cell phone designers have avoided use of DRAM in cell phones out of a concern that the refresh requirements thereof will adversely impact battery life, a critical parameter for cell phones.

However, current cell phone applications require higher data rates. Higher data rates require more data space, which leads to a need for greater memory capacity. Hence, a need exists in the art for a system or method for using DRAM in cell phones while minimizing the power consumption associated therewith.

### SUMMARY OF THE INVENTION

The need the art is addressed by the memory refresh system and method of the present invention. Generally, the inventive system includes a mechanism for selectively refreshing elements of a memory array in response to signals from a conventional memory management system.

In the illustrative application, the memory is dynamic random access memory and the inventive system is adapted to provide for selective refresh of those DRAM memory elements to which data has been or will be stored. This allows for the use of advantageous DRAM memory elements while minimizing the power consumption thereof. Consequently, the utility of DRAM memory elements is extended to a variety of power sensitive applications including cellular telephony and mobile computing.

In a specific embodiment, the inventive system includes a first counter for counting clock pulses and providing a first count in response thereto; a first comparator for comparing the count to a refresh interval and providing refresh pulses in response thereto; a second counter for generating a reset the signal in response to the refresh pulses and a refresh address range; and a third counter for generating a refresh address pointer in response to the refresh signal and the reset signal. In the illustrative application, the memory elements are dynamic random access memory elements. Nonetheless, the present teachings are not limited thereto.

A novel wireless communication system is disclosed and claimed herein. The novel wireless indication system includes a transceiver for transmitting and receiving electromagnetic signals; a modem for converting the electromagnetic signals to digital signals and vice versa; memory and a memory management system for storing at least some of the digital signals in predetermined memory elements; a system for selectively refreshing the predetermined memory elements; and an arrangement for providing user input and output. In the illustrative embodiment, the wireless communication system includes dynamic random access memory.

### BRIEF DESCRIPTION OF THE DRAWINGS

FIG. 1 is a block diagram showing an illustrative embodiment of a wireless communication system implemented in accordance with the teachings of the present invention.

FIG. 2 is a block diagram showing an illustrative implementation of the refresh control logic of FIG. 1.

FIG. 3 is a block diagram of an illustrative implementation of the second counter circuit shown in FIG. 2.

### DESCRIPTION OF THE INVENTION

Illustrative embodiments and exemplary applications will now be described with reference to the accompanying drawings to disclose the advantageous teachings of the present invention.

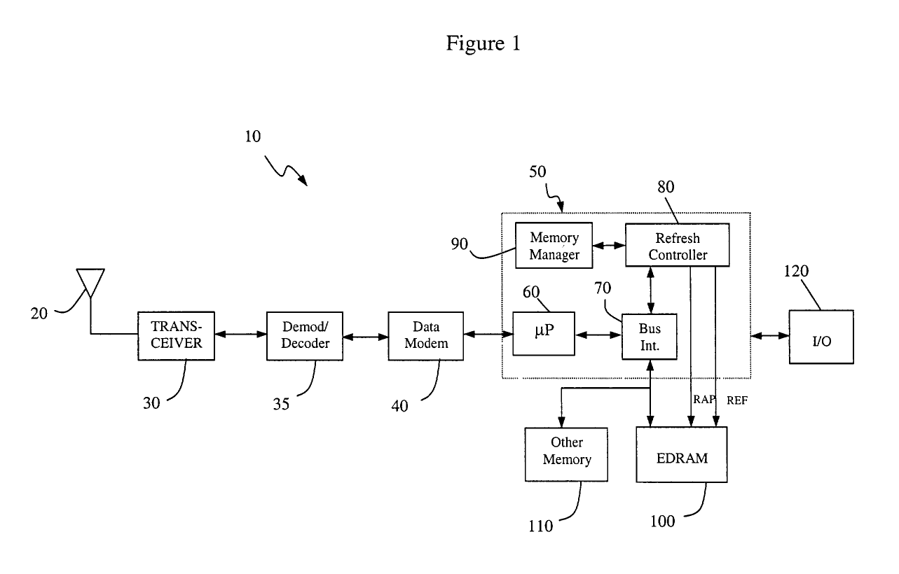

FIG. 1 is a block diagram showing an illustrative embodiment of a wireless communication system implemented in accordance with the teachings of the present invention. The system 10 includes an antenna 20 coupled to a transceiver 30. The transceiver 30 includes a radio frequency transmitter and receiver along with circuitry for up converting and down converting signals as is well known in the art. The transceiver circuit 30 communicates demodulator/decoder 35 which converts the received signals to baseband and converts baseband signals to RF frequencies. The demodulator/decoder 35 communicates with a data modem 40 of conventional design and construction. The data modem 40 sends digital signals to and receives digital signals from a system controller 50. In the best mode, the system controller 50 is implemented on a single chip as mobile station modem application specific integrated circuit (MSM ASIC). The system controller 50 includes a microprocessor 60 which, in accordance with the present teachings, communicates with dynamic random access memory (DRAM) 100 and other memory 110 via a bus interface 170. In an embodiment, the MSM ASIC is integrated with embedded dynamic random access memory (EDRAM).

In accordance with the present teachings and as discussed more fully below, power consumption of the DRAM 100 is minimized by a refresh control logic 80 which operates under control of the microprocessor 60 via the interface bus 70 in response to inputs from a memory manager or controller 90. The memory manager 90 is typically implemented in software in an operating system running on the communication system 10. The communication system 10 further includes user input and output devices which are represented generally at 120.

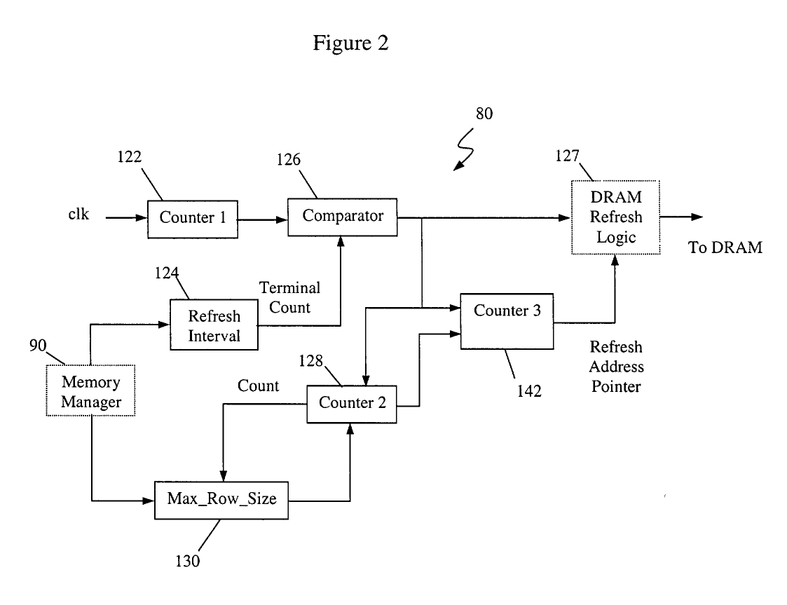

FIG. 2 is a block diagram showing an illustrative implementation of the refresh control logic 80 of FIG. 1. As shown in FIG. 2, in the illustrative embodiment, the refresh control logic 80 is implemented as a state machine with a first counter 122 that counts clock pulses and provides a first count to a first comparator 126. The comparator 126 compares the first count to a refresh interval stored in a register 124. The refresh interval stored in the register 124 is provided by the memory manager 90 and represents the terminal count for the comparator 126. When the first count from the first counter 122, reaches the terminal count, the compare 126 outputs a refresh pulses to the DRAM 100 via conventional DRAM refresh logic 127.

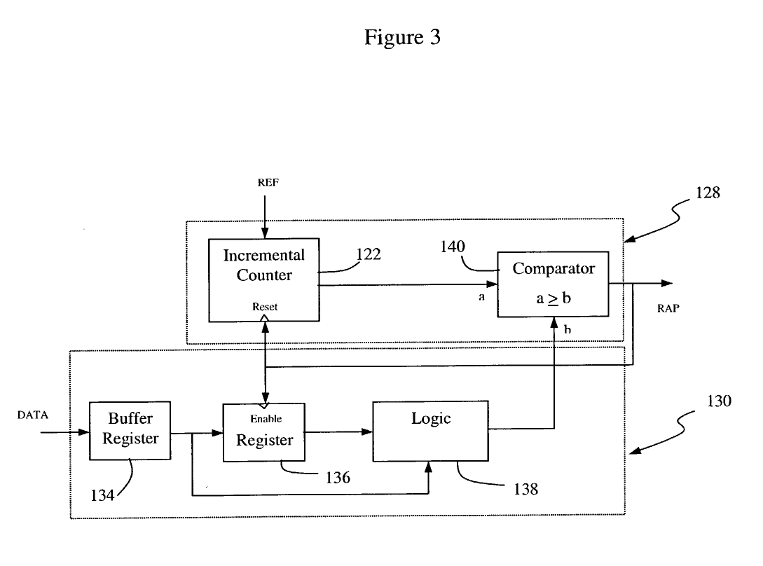

The refresh pulses are also counted by a second counter 128 disposed within the refresh control logic 80. In the illustrative embodiment, the second counter 128 is implemented with a logic circuit as illustrated more fully in FIG. 3 below.

FIG. 3 is a block diagram of an illustrative implementation of the second counter circuit shown in FIG. 2. As illustrated in FIG. 3, the second counter circuit 128 includes an incremental counter 132, which receives the refresh pulses from the first comparator 126 of FIG. 2. The output of the counter 132 is supplied to a second comparator 140. The second comparator 140 generates a reset address pointer signal ‘RAP’ when the count of the counter 132 exceeds the address range stored in the register 130.

As illustrated in FIGS. 2 and 3, the refresh address range is supplied by the memory manager 90. The refresh address range may be the memory cells in the DRAM 100 to which data has been or will be written by the memory manager 90. In the event a default minimum address is utilized, only the upper limit on the range need be specified. This approach is utilized in the illustrative embodiment. Consequently, a register 130 is used in conjunction with the counter 128 to supply the upper limit on the refresh address range thereto. In the illustrative embodiment, this upper limit is represented by the label ‘max_row_size’. In the best mode, the register 130 includes a buffer register 134 for storing a new value for the address range and a second register 136 for storing the current value of the refresh address range ‘max_row_size’. The second counter 128 generates one RAP pulse every ‘max_row_size’. A logic circuit 138 compares the output of the to register is 134 and 136 and implements the algorithm set forth below to ensure that as max_row_size is updated, it is set such that every row gets refreshed within the data retention time:

if new size>old size, counter 2 counts to old size, generates RAP, wrap-around to zero, then uses new size as the terminal count

if new size<old size,

2a) if new size≦current count of counter 2 it is therefore <old size, thus, generate RAP, wrap-around to zero and use new size as terminal count

2b) if current count of counter 2<new size, immediately use new size as terminal count;

where ‘old size’ is the previous value for ‘max_row_size’ and ‘new size’ is the updated value for ‘max_row_size’. Those of ordinary skill in the art will be able to implement a suitable logic circuit 138 adapted to implement the above algorithm without undue experimentation.

The output of the logic circuit 138 is compared to the output of the counter 132 by the comparator 140. When the count output by the counter 132 equals or exceeds the address range provided by the logic circuit 138, the comparator 140 outputs a reset address pointer signal ‘RAP’.

The refresh interval and max_row_size should satisfy the following condition:

refresh_interval•max_row_size<data retention time [1]

The refresh interval controls how often DRAM is refreshed and therefore the refresh current consumed by the DRAM. It should be chosen as large as possible while still satisfying equation [1]. This results in minimum refresh current compatible with the size of the memory. Max_row_size controls the amount of memory refreshed and can be determined from the data memory requirement of the system by the memory manager.

To reduce the amount of the memory refreshed, reduce max_row_size first. After a reset pulse RAP is generated, the refresh_interval can then be increased as long as equation [1] is satisfied.

To increase the amount of memory refreshed, first reduce the refresh_interval so that equation [1] is satisfied even for the increased max_row_size, then increase max_row_size as desired.

Returning to FIG. 2, the refresh pulses are counted by a third counter 142. In the best mode, the third counter 142 is implemented on the DRAM chip. The third counter 132 provides a refresh address pointer to the DRAM refresh logic 127. As is well-known in the art, the DRAM refresh logic 127 refreshes the DRAM row specified by the third counter when a refresh pulse is received. The third counter 142 is reset by the RAP signal from the second counter 128.

Thus, the present invention has been described herein with reference to a particular embodiment for a particular application. Those having ordinary skill in the art and access to the present teachings will recognize additional modifications, applications and embodiments within the scope thereof.

If is therefore intended by the appended claims to cover any and all such applications, modifications and embodiments within the scope of the present invention.

1. A memory refresh system comprising:
memory management means for identifying a subset of a plurality of storage elements of a memory and
means for selectively refreshing said subset of said elements of said memory.

2. The invention of claim 1 wherein said memory is dynamic random access memory.

3. The invention of claim 1 wherein said means for refreshing said subset of elements includes means for generating refresh pulses.

4. The invention of claim 3 wherein said means for generating a refresh pulses includes a first counter.

5. The invention of claim 4 wherein said first counter is adapted to count clock pulses and provide a first count in response thereto.

6. The invention of claim 5 wherein said means for generating refresh pulses further includes means for providing a refresh interval.

7. The invention of claim 6 wherein an output of said means for providing a refresh interval is a terminal count.

8. The invention of claim 7 wherein said means for generating refresh pulses includes a comparator adapted to compare said count to said terminal count and provide said refresh pulses in response thereto.

9. The invention of claim 1 wherein said means for refreshing said subset of elements includes means for generating a refresh address pointer.

10. The invention of claim 9 wherein said means for generating a refresh address pointer includes first means for counting said refresh pulses and providing a first count with respect thereto.

11. The invention of claim 10 wherein said means for generating a refresh address pointer includes means for providing a refresh address range.

12. The invention of claim 11 wherein said means for generating a refresh address pointer includes means for comparing said count to said refresh address range and providing a refresh address pointer reset signal in response thereto.

13. The invention of claim 12 wherein said means for generating a refresh address pointer includes second means for counting said refresh pulses and providing a second count with respect thereto.

14. The invention of claim 13 wherein said second means includes a second counter adapted to count said refresh pulses and provide said refresh address pointer in response thereto.

15. The invention of claim 14 wherein said second counter is adapted to receive said refresh address pointer reset signal as a reset signal therefor.

16. A system for refreshing a subset of an array of memory elements comprising:
a first counter adapted to count clock pulses and provide a first count in response thereto;
a first comparator adapted to compare said count to a refresh interval and provide refresh pulses in response thereto;
a second counter for generating an intermediate signal in response to said refresh pulses and a refresh address range; and
a third counter for generating a refresh address pointer in response to said refresh signal and said intermediate signal.

17. The invention of claim 16 wherein said memory elements are dynamic random access memory elements.

18. A memory refresh system comprising:
a first counter adapted to receive clock pulses and provide a first count in response thereto;
a first register for providing a refresh interval;
a first comparator adapted to receive the output of said first counter and the output of said first register as inputs;
a second counter adapted to receive the output of said to comparator as an input thereto;
a second register for providing a refresh address range;
a second comparator adapted to receive the output of said second counter and said second register as inputs and provide a refresh address pointer reset signal in response thereto;
a third counter responsive to said a reset signal and adapted to count said refresh pulses and provide a refresh address pointer in response thereto; and
means for refreshing memory elements in response to said refresh pulses and said refresh address pointer.

19. The invention of claim 18 wherein said memory elements are dynamic random access memory elements.

20. A communication system comprising:
first means for transmitting and receiving electromagnetic signals;
second means for converting said electromagnetic signals to digital signals;
third means for storing at least some of said digital signals in predetermined memory elements;
fourth means for selectively refreshing said predetermined memory elements; and
fifth means coupled to said first, second and third means for providing user input and output.

21. The invention of claim 20 wherein said memory elements are dynamic random access memory elements.

22. A method for refreshing a memory including the steps of:
identifying a subset of a plurality of storage elements of a memory and
selectively refreshing said subset of said elements of said memory.

23. The invention of claim 22 wherein said subset of memory elements is a set of memory elements to which data has been written.

24. The invention of claim 22 wherein said subset of memory elements is a set of memory elements to which data may be written.

25. The invention of claim 22 wherein said memory is dynamic random access memory.
